(19) United States
(12) Patent Application Publication
(10) Pub. No.: US 2009/0160524 A1
(43) Pub. Date: Jun. 25, 2009

(54) LEVEL SLIDER CIRCUIT

(75) Inventors: Ulrich Theus, Freiburg (DE); Jurgen Giehl, Kirchzarten (DE); Martin Czech, Eschbach (DE)

Correspondence Address: DUANE MORRIS LLP - Princeton, PO BOX 5203, PRINCETON, NJ, 08543-5203, US

(73) Assignee: Micronas GmbH, Freiburg (DE)

(21) Appl. No.: 12/257,505

(22) Filed: Oct. 24, 2008

(30) Foreign Application Priority Data
Oct. 26, 2007 (DE) 10 2007 051 648.9

(51) Int. Cl. H03L 5/00

(52) U.S. Cl. 327/333

(57) ABSTRACT

The invention relates to a level slider circuit having a first level slider (1) and a second level slider (2) switched in series for the conversion of an input signal (Vᵢₙ) from a first operating voltage range (A) at a first ground voltage (V_{SSA}) and a first supply voltage (V_{DDA}) into an output signal (Vₒᵤₜ) in a second operating voltage range (B) at a second ground voltage (V_{SSB}) and a second supply voltage (V_{DDB}), wherein the first level slider (1) is embodied for the conversion of the input signal (Vᵢₙ) to the ground voltage (V_{SSA}) of the second operating voltage range (B) for the conversion of the input signal (Vᵢₙ), and that the second level slider (2) is embodied for the conversion of an intermediate signal (V_{Z}) output by the first level slider (1) to the output signal travel (ΔVₒᵤₜ).

The invention relates to a level slider circuit according to the generic characteristics of patent claim 1.

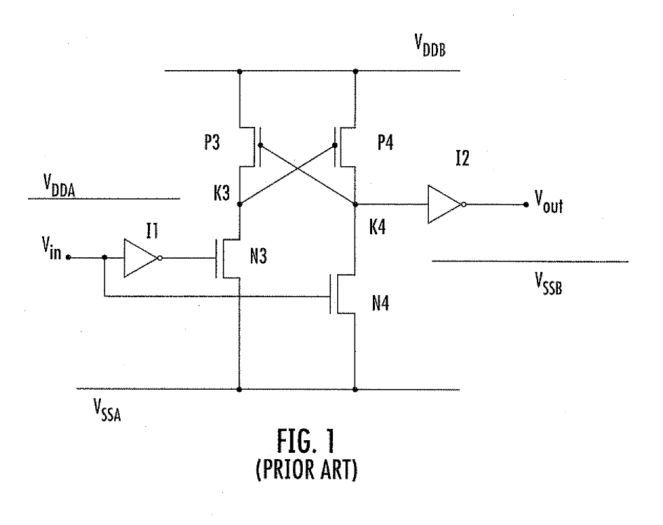

Level slider circuits are known from prior art in order to adjust signal levels between sections having different supply voltages. A level slider circuit known from prior art is illustrated in FIG. 1. The level slider circuit serves for transmitting an input signal Vᵢₙ from a first operating voltage range A at a first ground voltage V_{SSA} and a first supply voltage V_{DDA} into an output signal Vₒᵤₜ in a second operating voltage range B at a second ground voltage V_{SSB} and a second supply voltage V_{DDB}. For this purpose the level slider is switched between the second supply voltage V_{DDB} and the first ground voltage V_{SSA}. The level slider is embodied as a parallel circuit from a series connection of a third p-channel transistor P3 and a third n-channel transistor N3, as well as a series connection of a fourth p-channel transistor P4 and a fourth n-channel transistor N4. The third p-channel transistor P3 and the fourth p-channel transistor P4 are cross-coupled, i.e. a control connection of the fourth p-channel transistor P4 is connected to a third junction point K3 between the third p-channel transistor P3 and the third n-channel transistor N3, and a control connection of the third p-channel transistor P3 is connected to a fourth junction point K4 between the fourth p-channel transistor P4 and the fourth n-channel transistor N4.

The input signal Vᵢₙ is inverted to a control connection of the third n-channel transistor N3 via a first inverter I1, and directly supplied to a control connection of the fourth n-channel transistor N4. The output signal Vₒᵤₜ can be tapped directly at the third junction point K3 and at the fourth junction point K4 in an inverted manner, and is converted to the second operating voltage range B. In the embodiment variation illustrated in FIG. 1 a second inverter I2 is connected to the junction point K4 such that the output signal Vₒᵤₜ can be tapped on the output side.

The mode of operation of the circuit described above is explained as follows, based on an example of the high signal applied as an input signal Vᵢₙ. The high signal on the input side is inverted by means of the first inverter I1, and is therefore applied as a low signal at the control input of the third n-channel transistor N3, with the transistor locking. Simultaneously, the high signal on the input side is applied directly to the control input of the fourth n-channel transistor N4 so that the same becomes conducting. Due to the fact that the fourth n-channel transistor N4 is conducting, the fourth junction point K4 is pulled to the first ground voltage V_{SSA}. Simultaneously, the first ground voltage V_{SSA} of the fourth junction point K4 is applied to the control input of the third p-channel transistor P3 by means of the cross-coupling, and the same become conducting. Due to the fact that the third p-channel transistor P3 is conducting, the third junction point K3 is pulled to the second supply voltage V_{DDB}. Due to the cross-coupling the second supply voltage V_{DDB} now in turn applied to the third junction point K3, is applied at the control connection of the fourth p-channel transistor P4 so that the same locks. The first ground voltage V_{SSA} can therefore be tapped at the fourth junction point K4, and is converted into a high signal for the second operating voltage range B by the second inverter I2, and can therefore be tapped as an output signal Vₒᵤₜ on the output side.

However, the described prior art has substantial disadvantages. For example, if a bad signal-to-noise ratio is present between the first operating voltage range A and the second operating voltage range B. If, for example, the first operating voltage range A is large, i.e. at V_{DDA}-V_{SSA}=3.3 V, and the second operating voltage range B is small, i.e. V_{DDB}-V_{SSB}=1 V, interferences may occur between the operating voltage systems A, B, which are just within this range. If the first ground voltage V_{SSA} at the stated values is increased by 1 V due to fluctuations or interferences, it is impossible to disconnect the junctions K3 and K4 from the second supply voltage V_{DDB}. The level slider therefore loses its function completely during such interferences, i.e. unforeseeable time delays occur in the circuit.

It is the object of the invention to provide a level slider circuit that operates reliably between the operating voltage ranges in case of interferences, and does not have the disadvantages of those according to prior art.

This object is solved by means of a level slider circuit having the characteristics of patent claim 1.

A level slider circuit according to the invention has a first level slider and a second level slider switched in series for converting an input signal having an input signal travel as a first operating voltage range having a first ground voltage and a first supply voltage into an output signal having an output signal travel into a second operating voltage range having a second ground voltage and a second supply voltage, wherein the first level slider is embodied for the conversion of the input signal to the ground voltage of the second operating voltage range, and the second level slider is embodied for the conversion of an intermediate signal output by the first level slider, into the output signal travel. The invention utilizes the knowledge that the problems according to prior art are based on fluctuations of the first ground voltage against the second supply voltage. The input signal is therefore initially transferred to the second ground voltage by means of a first level slider, wherein, however, the input travel of the input signal still remains intact. The intermediate signal now applied on the second ground voltage is converted to the lower level of the second operating voltage range with the still large input travel via a second level slider. The action according to the invention displaces the fluctuations in the first level slider, at which location the same can be more easily tolerated due to the larger operating voltage region and the inherent larger input signal travel.

Advantageous further improvements of the invention are the object of the sub-claims.

The invention is explained in further detail below, based on an exemplary embodiment with reference to the attached figures.

They show:

FIG. 1 already discussed, a level slider according to prior art,

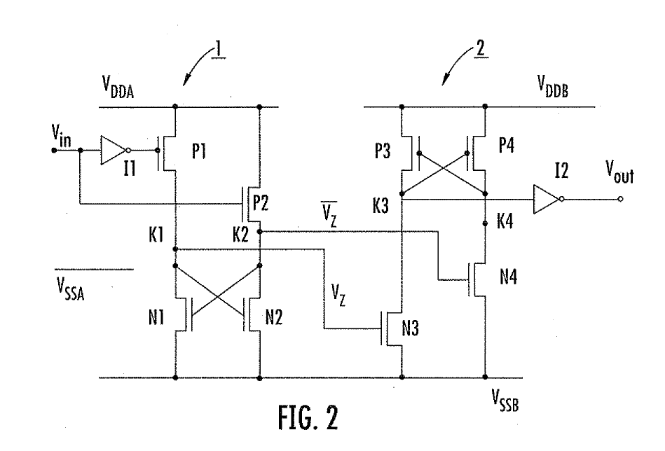

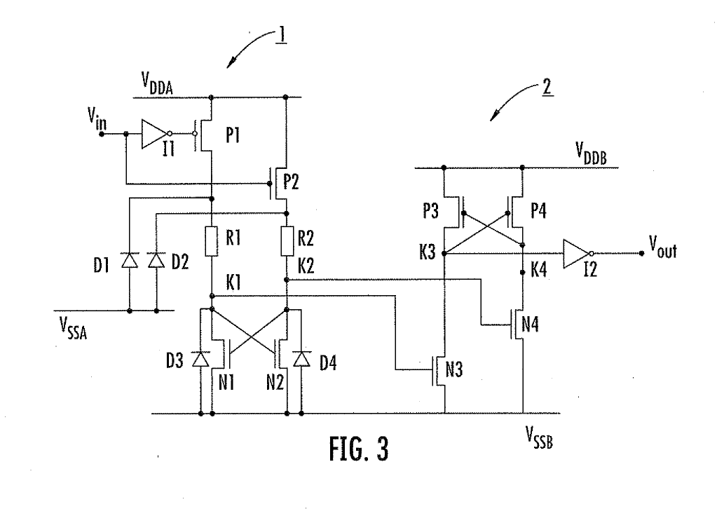

FIG. 2 a level slider according to the invention,

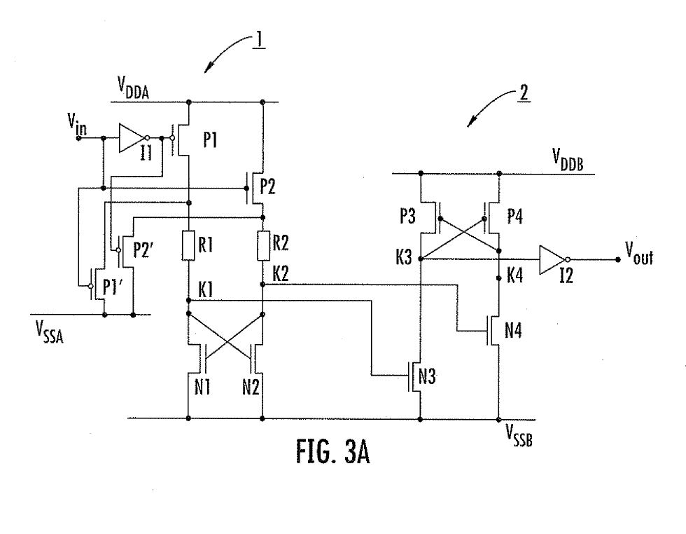

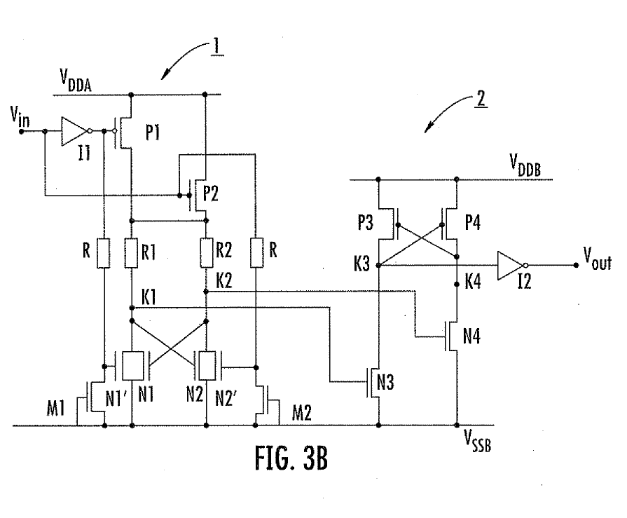

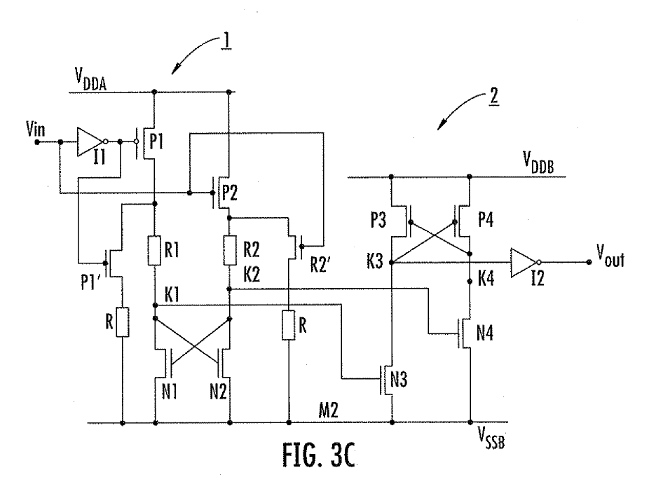

FIG. 3 a level slider according to the invention having an ESD protective circuit,

FIG. 3a the level slider circuit of FIG. 3 having additional p-channel transistors against V_{SSA} for rapid switching,

FIG. 3b the level slider circuit of FIG. 3 having MOS clamping diodes, and

FIG. 3c the level slider circuit of FIG. 3 having additional p-channel transistors against V_{SSB}.

FIG. 2 illustrates an exemplary embodiment of a level slider circuit for transferring an input signal Vᵢₙ from a first operating voltage range A to an output signal Vₒᵤₜ in a second operating voltage range B. For this purpose the first operating voltage range A has a first ground voltage V_{SSA} and a first supply voltage V_{DDA}. The second operating voltage range B has a second ground voltage V_{SSB} and a second supply voltage V_{DDB}. The first level slider 1 is embodied as a parallel circuit from a first series connection of a first p-channel transistor P1 and of a first n-channel transistor N1 having a second series connection of a second p-channel transistor P2 and of a second n-channel transistor N2. The first n-channel transistor N1 and the second n-channel transistor N2 are cross-coupled, i.e. a control input of the second n-channel transistor N2 is connected to a first junction point K1 between the first p-channel transistor P1 and the first n-channel transistor N1, and a control input of the first n-channel transistor N1 is connected to a second junction point K2 between the second p-channel transistor P2 and the second n-channel transistor N2. The input signal Vᵢₙ is inverted to the first p-channel transistor P1 by means of an upstream inverter I1, and can be supplied to the second p-channel transistor P2 directly. An intermediate signal V_{Z} can be tapped directly at the second junction point K2 in an inverted manner.

The intermediate signal V_{Z} can be supplied to a second level slider 2, which is switched between the second supply voltage V_{DDB} and the second ground voltage V_{SSB}. The second level slider 2 is embodied as a parallel circuit from a third series connection of a third p-channel transistor P3 and of a third n-channel transistor N3, and a fourth series connection of a fourth p-channel transistor P4 and of a fourth n-channel transistor N4. The third p-channel transistor P3 and the fourth p-channel transistor P4 are cross-coupled, i.e. a control input of the fourth p-channel transistor P4 is connected to a third junction point K3 between the third p-channel transistor P3 and the third n-channel transistor N3, and a control input of the third p-channel transistor P3 is connected to a fourth junction point K4 between the fourth p-channel transistor P4 and the fourth n-channel transistor N4. The intermediate signal VZ can be supplied to the third n-channel transistor N3 directly, and to the fourth n-channel transistor N4 in an inverted manner. In the present exemplary embodiment a control input of the third n-channel transistor N3 is connected to the first junction point K1, and a control input of the fourth n-channel transistor N4 is connected to the second junction point K2, on which the respective signals can be tapped. The output signal Vₒᵤₜ is then inverted at the third junction point K3, and can be tapped directly at the fourth junction point K4.

In the embodiment variation illustrated in FIG. 2 the tap occurs at the third junction point K3 via a second inverter I2 such that the output signal Vₒᵤₜ can be tapped at the second inverter 12 at the output side.

The mode of operation of the circuit illustrated is explained below, based on an applied high signal. Exemplary operating voltage ranges A, B may be operated, for example, at V_{DDA}-V_{SSA}=3.3 V and at V_{DDB}-V_{SSB}=1 V. At such a configuration, a level slider known from prior art, as is illustrated in FIG. 1, may no longer be functional with any fluctuation of the first ground voltage V_{SSA} by ±1 V, since an excitation of the junctions K3, K4 is no longer possible. In a level slider circuit according to the invention, as illustrated in FIG. 2, the fluctuations of the first ground voltage V_{SSA} against the second supply voltage V_{DDB} due to the switching of the level slider 1, 2 is no longer critical. Any fluctuations, which may occur between the first supply voltage V_{DDA} and the second ground voltage V_{SSB} are displaced to the first n-channel transistor N1 and to the second n-channel transistor N2. At this point, fluctuations of, for example, ±1 V may be more easily tolerated due to the high input signal travel ΔVᵢₙ in the first supply voltage range A. A high signal on the input side, having an input signal travel ΔVᵢₙ of, for example ΔVᵢₙ=V_{DDA}=3.3 V, is applied to the first p-channel transistor P1 as a low signal by means of the first inverter I1 such that the first p-channel transistor P1 is in a conducting state. Simultaneously, the high signal on the input side is applied directly to the second p-channel transistor P2 so that the same locks. The first junction K1 is pulled to the potential of the first supply voltage V_{DDA} by the conducting first p-channel transistor P1, by means of which the first supply voltage V_{DDA} is applied to the second n-channel transistor N2, and switches the same in a conducting manner. The second junction point K2 is pulled to the potential of the second ground voltage V_{SSB} of the second operating voltage range B by the conducting second n-channel transistor N2. Due to the cross-coupling of both n-channel transistors N1, N1 the second ground voltage V_{SSB} is therefore applied to the control connection of the first n-channel transistor N1 so that the same locks. In summary, the first supply voltage V_{DDA} is applied at the first junction point K1, and the second ground voltage V_{DDB} is applied to the second junction point K2, and they are supplied to the second level slider 2 as the intermediate signal V_{Z}. The first supply voltage V_{DDA} is therefore applied to the third n-channel transistor N3 such that the same is in a conducting state. The third junction point K3 is therefore pulled to the level of the second ground voltage V_{SSB}. The second ground voltage V_{SSB} is applied to the fourth n-channel transistor N3 so that the same locks. Due to the potential of the second ground voltage V_{SSB} applied to the third junction point K3 the fourth p-channel transistor P4 is switched via the cross-coupling in a conducting manner. The fourth junction point K4 is pulled to the potential of the second supply voltage V_{DDB} by means of the conducting fourth p-channel transistor P4. The third p-channel transistor P3 is locked via the cross-coupling. In summary, the second ground voltage V_{SSB} is now applied to the junction point K3, and the second supply voltage V_{DDB} is applied to the fourth junction point K4, and they can be tapped on the output side. In the current example the low signal applied to the third junction point IK3 is tapped via the second inverter I2 in an inverted manner, and is provided on the output side as a high signal having an output signal travel ΔVₒᵤₜ=V_{DDB}=1 V.

FIG. 3 illustrates the level slider circuit from FIG. 2, wherein additional measures are provided for the protection from over-voltages and high currents. As illustrated in FIG. 3, so-called ESD protective circuits may be realized, for example, by means of clamping diodes D1, D2, which clamp the output of the first p-channel transistor P1 and of the second p-channel transistor P2 to the first ground voltage V_{SSA}. The p-channel transistor P2′, which is also connected to the first ground voltage V_{SSA}, is connected downstream of the second p-channel transistor P2. The input signal Vᵢₙ can be supplied directly to a control input of the p-channel transistor P1′, wherein the input signal Vᵢₙ can be supplied to a control input of the p-channel transistor P2′ in an inverted manner. The two p-channel transistors P1′, P2′ have the advantage that a signal change to the second ground voltage V_{SSB} can occur at the first junction point K1 and at the second junction point K2 even faster than described in the exemplary embodiment in FIG. 3, and that no parasitic bipolar effects may occur by means of such an interconnection.

FIG. 3b shows the level slider of FIG. 3, wherein the clamping diodes D1 to D1 are not provided. An n-channel transistor N1′, N2′ is connected in parallel to the first n-channel transistor N1 and the second n-channel transistor N2. A control input of the n-channel transistor N1′ is connected to the second ground voltage V_{SSB} via a first MOS clamping diode M1. The first MOS clamping diode M1 is realized as an n-channel transistor, the control input of which is permanently connected to the second ground voltage V_{SSB}. Furthermore, the inverted input signal Vᵢₙ can be supplied to the control input of the n-channel transistor N1′ via a resistor R. A control input of the n-channel transistor N2′ is connected to the second ground voltage V_{SSB} via a second MOS clamping diode M2. The second MOS clamping diode M2 is also realized as an n-channel transistor, the control input of which is permanently connected to the second ground voltage V_{SSB}. Furthermore, the input signal Vᵢₙ can be supplied to the control input of the n-channel transistor N2′ via a resistor R.

FIG. 3c shows the level slider of FIG. 3, wherein the clamping diodes D1 to D4 are not provided. In this case, a series connection from a p-channel transistor P1′ and from a resistor R are connected in parallel to the first resistor R1 and the first n-channel transistor N1. The inverted input signal Vᵢₙ can be supplied to a control input of the p-channel transistor P1′. A series connection from a p-channel transistor P2′ and from a resistor R is connected in parallel to the second resistor R2 and the second n-channel transistor N2. The input signal Vᵢₙ can be supplied to a control input of the p-channel transistor P2′. This embodiment has the advantage that any dynamic deflections of the first ground voltage V_{SSA} do not have any effect on the level slider.

In closing it should be noted that the precise arrangement of the inverters is not mandatory for the function of the circuit principle. The crucial factor is the interconnection of the level sliders 1, 2, by means of which a displacement of the interferences occurs in the first level slider 1, in which the interferences are more easily tolerated due to the larger input signal travel ΔVᵢₙ and the larger operating voltage range.

A level slider circuit according to the invention can be utilized, for example, in any CMOS circuit; this is of particular advantage, if a low signal-to-noise ratio is present at the transition between the first operating voltage range 1 and the second operating voltage range B. Furthermore, the use is also possible in any integrated circuit. The principle according to the invention may also be utilized in discrete circuits, which, for example, may be configured as individual transistors. In particular, it is also possible to utilize bipolar transistors for creating a level slider circuit according to the invention.

### LIST OF REFERENCE SYMBOLS

1 first level slider
2 second level slider
D1 first diode
D2 second diode
D3 third diode
D4 fourth diode
K1 first junction point
K2 second junction point
K3 third junction point
K4 fourth junction point
P1 first p-channel transistor
P2 second p-channel transistor
P3 third p-channel transistor
P4 fourth p-channel transistor
P1′ p-channel transistor
P2′ p-channel transistor
N1 first n-channel transistor
N2 second n-channel transistor
N3 third n-channel transistor
N4 fourth n-channel transistor
N1′ n-channel transistor
N2′ n-channel transistor
I1 first inverter
I2 second inverter
R resistor
R1 resistor
R2 resistor
M1 first MOS clamping diode
M2 second MOS clamping diode
V_{SSA} first ground voltage
V_{DDA} first supply voltage
V_{SSB} second ground voltage
V_{DDB} second supply voltage
Vᵢₙ input signal
Vₒᵤₜ output signal
V_{z} intermediate signal
ΔVᵢₙ input signal travel
ΔVₒᵤₜ output signal travel
I1 first inverter
I2 second inverter
A first operating voltage range
B second operating voltage range

1. A level slider circuit having a first level slider (1) and a second level slider (2) switched in series for the conversion of an input signal (Vᵢₙ) from a first operating voltage range (a) at a first ground voltage (V_{SSA}) and a first supply voltage (V_{DDA}) into an output signal (Vₒᵤₜ) in a second operating voltage range (b) at a second ground voltage (V_{SSB}) and a second supply voltage (V_{DDB}),
characterized in that
the first level slider (1) is embodied for the conversion of the input signal (Vᵢₙ) to the ground voltage (V_{SSA}) of the second operating voltage range (b) for the conversion of the input signal (Vᵢₙ), and that the second level slider (2) is embodied for the conversion of an intermediate signal (V_{Z}) output by the first level slider (1) to the output signal travel (ΔVₒᵤₜ).

2. The level slider circuit according to claim 1,
characterized in that
the first level slider (1) is switched between the first supply voltage (V_{DDA}) and the second ground voltage (V_{SSB}), and is embodied as a parallel circuit from a first series connection of a first p-channel transistor (P1) and a first n-channel transistor (N1), and a second series connection of a second p-channel transistor (P2) and a second n-channel transistor (N2), that the input signal (Vᵢₙ) can be supplied to the first p-channel transistor (P1) in an inverted manner, and can be supplied directly to the second p-channel transistor (P2), that a control connection of the second n-channel transistor (N2) is connected to a first junction point (K1) between the first p-channel transistor (P1) and the first n-channel transistor (N1), that a control connection of the first n-channel transistor (N1) is connected to a second junction point (K2) between the second p-channel transistor (P2) and the second n-channel transistor (N2), and that the intermediate signal (V_{Z}) can be tapped at the first junction point (K1) directly, and can be tapped at the second junction point (K2) in an inverted manner.

3. The level slider circuit according to claim 1,
characterized in that
the second level slider (2) is switched between the second supply voltage (V_{DBB}) and the second ground voltage (V_{SSB}), and is embodied as a parallel circuit from a third series connection of a third p-channel transistor (P3) and a third n-channel transistor (N3), and a fourth series connection of a fourth p-channel transistor (N4), that the intermediate signal (V_{Z}) can be supplied to the third p-channel transistor (P3) directly, and can be supplied to the fourth p-channel transistor (P4) in an inverted manner,
that a control connection of the fourth n-channel transistor (N4) is connected to a third junction point (K3) between the third p-channel transistor (P3) and the third n-channel transistor (N3), that a control connection of the third n-channel transistor (N3) is connected to a fourth junction point (K4) between the fourth p-channel transistor (P4) and the fourth n-channel transistor (N4), and that
the output signal (Vₒᵤₜ) can be tapped at the third junction point (K3) in an inverted manner, and can be tapped at the fourth junction point (K4) directly.

4. The level slider circuit according claim 1,
characterized in that
an electrode voltage is larger between the first supply voltage (V_{DDA}) and the first ground voltage (V_{SSA}) than an electrode voltage between the second supply voltage (V_{DDB}) and the second ground voltage (V_{SSB}).

5. The level slider circuit according to claim 1,
characterized in that
the input signal (Vᵢₙ) and the output signal (Vₒᵤₜ) are digital signals.

6. The level slider circuit according to claim 1,
characterized in that
ESD protective circuits are provided.

7. The level slider circuit according to claim 6,
characterized in that
as the ESD protective circuits, a first resistor (r1) is switched between the first p-channel transistor (P1) and the first junction point (K1), and a second resistor (R2) is switched between the second p-channel transistor (P2) and the second junction point (K2).

8. The level slider circuit according to claim 6,
characterized in that
as the ESD protective circuits, a first clamping diode (D1) is switched between a signal output of the first p-channel transistor (P1) and the first ground voltage (V_{SSA}), and a second clamping diode (D2) is switched between a signal output of the second p-channel transistor (P2) and the first ground voltage (V_{SSA}).

9. The level slider circuit according to one of the claim 6,
characterized in that
as the ESD protective circuits, a third clamping diode (D3) is switched between the first junction point (K1) and the second ground voltage (V_{SSB}) and a fourth clamping diode (D4) is switched between the second junction point (K2) and the second ground voltage (V_{SSB}).

10. The level slider circuit according to claim 1,
characterized in that
the circuit is embodied as an integrated circuit.

11. The level slider circuit according to claim 7,
characterized in that
as the ESD protective circuits, a first clamping diode (D1) is switched between a signal output of the first p-channel transistor (P1) and the first ground voltage (V_{SSA}), and a second clamping diode (D2) is switched between a signal output of the second p-channel transistor (P2) and the first ground voltage (V_{SSA}).

12. The level slider circuit according to claim 8,
characterized in that
as the ESD protective circuits, a third clamping diode (D3) is switched between the first junction point (K1) and the second ground voltage (V_{SSB}) and a fourth clamping diode (D4) is switched between the second junction point (K2) and the second ground voltage (V_{SSB}).
